(19) United States
(12) Patent Application Publication
(10) Pub. No.: US 2008/0076077 A1
(43) Pub. Date: Mar. 27, 2008

(54) Apparatus and method for heating semiconductor wafers with improved temperature uniformity

(75) Inventor: Seiji Nakagawa, Oita-city (JP)

Correspondence Address: BANNER & WITCOFF, LTD., 1100 13th STREET, N.W., SUITE 1200, WASHINGTON, DC, 20005-4051, US

(73) Assignee: Toshiba America Electronic Components, Inc., Irvine, CA (US)

(21) Appl. No.: 11/524,291

(22) Filed: Sep. 21, 2006

(51) Int. Cl. G03F 7/26

(52) U.S. Cl. 430/330

(57) ABSTRACT

Apparatuses and methods for heating semiconductor wafers with high temperature uniformity are described. In particular, rotation of the hot plate and/or wafer during heating operations such as the post exposure bake (PEB) can compensate for non-circular temperature gradients caused by the random generation of air currents and other non-uniform environmental conditions within the oven chamber. Temperature variations caused by these influences, while not easily corrected through zonal heater adjustment alone, are a major determinant of critical dimension control and consequently the overall semiconductor quality.

### FIELD OF TECHNOLOGY

Aspects of the present disclosure describe an apparatus and method for improving the temperature uniformity of semiconductor wafers during heating operations, used in the manufacture semiconductor chips by photolithography. Such heating operations include the post exposure bake (PEB).

### BACKGROUND

Integrated circuits (semiconductors) are the key components of modern computers, communication systems, consumer electronics, and the new generations of smart machines and instruments. Microlithography is one of the most critical elements of the semiconductor manufacturing process because it determines the minimum feature size and the functional capabilities of the semiconductor. The quality of the microlithography process also greatly impacts the yield and cost of semiconductors and hence the competitiveness of the electronics industry. Advances in microlithographic imaging techniques and materials have played a key role in the remarkable evolution of semiconductor devices and circuits.

A primary driver of continuing miniaturization, leading to improved performance and lower cost, is critical dimension (CD) control. The CD refers to the dimension of the smallest geometrical features (width of interconnect lines, contacts, trenches, etc.) which can be formed during semiconductor device/circuit manufacturing using given technology. Recent advances in photosensitive materials, or resists, has elevated the post exposure bake (PEB) thermal step in semiconductor manufacturing to the primary determinant of CD control. The PEB is used to smooth out surface features known as “standing waves” remaining in the resist after exposure, for example, to deep-ultraviolet (DUV) radiation. The PEB also affects the resist profile in other important ways.

For a class of resists known as chemically amplified resists, the PEB initiates chemical reactions that create a solubility difference between exposed and unexposed parts of the resist, in order to amplify a DUV-induced latent image. In particular, with these resists, the initial exposure typically generates a small amount of acid. During PEB, this radiation-generated acid is used to catalyze a reaction that changes the solubility of the polymer resin in the resist. Control of the PEB is therefore extremely critical for chemically amplified resists.

The PEB is normally performed by placing the semiconductor lithography wafer in an oven module after lithographical exposure. The oven generally contains a large-surfaced hot plate to heat all areas of the wafer, to the greatest extent possible, to a constant temperature. Such temperature uniformity has emerged as a major consideration in semiconductor manufacturing, in view of the improved resists that have led to the tighter final CD uniformity requirements discussed above. Because temperature variations encountered during PEB are recognized as having a direct and significant correlation to final CD variation, standard PEB process temperature variation tolerances in many cases have dramatically decreased from previous values of 0.5-1.0° C. (0.9-1.8° F.) to less than 0.25° C. (0.45° F.). Even seemingly minor temperature variations during the PEB can substantially alter resist hardening, resulting in reduced image line and CD control.

Theoretically, all portions of a wafer should bake and harden at precisely the same rate when subjected to identical temperatures for identical times. In practice however, such exact uniformity is difficult to achieve. Efforts to address stringent temperature uniformity requirements have focused primarily on the use of multi-zone and/or multi controller hot plates. This has led to some improvements in the temperature uniformity achieved during the PEB of semiconductor wafers. However, these improvements primarily address the so-called “circular” or radial temperature variations that are uniform along any given radius of the wafer during heating. The associated temperature control schemes are also in many cases complex and rely on expensive detectors such as infrared cameras, linewidth image measuring devices, pyroelectric detectors, etc. in or around the oven environment.

Regardless of the measured quantity used for feedback control, the regulation of oven heater zone settings, unfortunately, has only limited effectiveness in correcting “non-circular”temperature variations caused by uncontrollable and often random influences such as the flow rate and direction of air currents which are generated in the oven environment. These factors are generally not constant throughout the heating process and can affect different areas of the oven chamber (e.g., areas proximate different sides of the wafer) in different ways. Moreover, these factors can lead to temperature variations over the surface of the wafer which exceed industry standards for PEB, ultimately to the detriment of the semiconductor wafer quality.

### SUMMARY

Aspects of the present disclosure describe illustrative apparatuses and methods for heating semiconductor wafers with high temperature uniformity. Techniques have been discovered that may at least partially compensate for both circular and non-circular temperature gradients on the wafer. Non-circular temperature gradients may be caused by the random generation of air currents and other non-uniform environmental conditions within the oven chamber during heating. Such conditions result from varying heat losses at the edges of the hot plate and/or the wafer, varying rates of heat transfer between the hot plate and wafer (particularly at the edges), varying rates of heat dissipation through the lid of the heating apparatus due to temperature variations on the internal and/or external surfaces of the lid, etc. Temperature variations during PEB and/or other wafer heating operations (e.g., soft bake prior to exposure) that are not easily corrected through zonal heater adjustment alone are therefore addressed herein.

In the case of PEB of a wafer having a chemically amplified resist, the techniques and apparatuses described herein are particularly suitable for establishing and maintaining wafer temperature uniformity during the critical initial 10-20 seconds of heating. During this time, the catalytic chemical reactions, discussed above, which change the resin solubility in the resist and ultimately control the features of the semiconductor, are substantially completed. Compared to many of the complex feedback control loops used to regulate zonal hot plate temperatures, as described above, the present invention offers a relatively simple and highly effective solution to the increasingly strict tolerances associated with temperature control during PEB and other wafer heating operations. As is recognized in the semiconductor industry, temperature uniformity is a major determinant of CD control and therefore the overall semiconductor quality.

The present disclosure is based on the realization that the non-circular temperature gradients described above may be greatly reduced or even eliminated by rotating the hot plate used to heat the semiconductor wafer during heating. Rotation of the hot plate effectively allows all portions of the wafer to be uniformly exposed to the same heating conditions within the oven. These conditions result not only from the settings of the one or more heaters used to control the hot plate and wafer temperature, but also from non-constant air current flows and/or eddies which typically affect one side of the wafer environment differently from another, causing non-circular temperature variations. In a representative semiconductor wafer heating apparatus, a rotatable hot plate may be spaced slightly above the surface of the heater.

A semiconductor heating operation such as the PEB may additionally involve rotating not only the hot plate, but also the semiconductor wafer itself. In one embodiment, for example, wafer holders may be mounted directly on the hot plate, such that rotation of the hot plate automatically results in rotation of the wafer at the same rate.

These wafer holders may also be used to either dispose the wafer directly on the hot plate surface or at a desired distance above the hot plate. In other embodiments, the hot plate may be rotated while the wafer is held stationary, or the hot plate and wafer may be rotated at different rates or even in different directions. The effectiveness of the various embodiments described herein in maintaining wafer temperature uniformity and other associated advantages will become apparent to those having skill in the art, having regard for the present disclosure.

Accordingly, in one embodiment, an apparatus for heating a semiconductor wafer is described. The apparatus comprises a rotatable hot plate disposed above a heater. In another embodiment, the rotatable hot plate is spaced apart from the heater, which may comprise a plurality of individually controllable heating elements. In another embodiment, the apparatus further comprises one or more holders on the rotatable hot plate for positioning the semiconductor wafer above the rotatable hot plate. In another embodiment, the one or more holders space the rotatable hot plate apart from the semiconductor wafer. In another embodiment, the apparatus further comprises a temperature sensor for measuring a temperature between the rotatable hot plate and the semiconductor wafer. In another embodiment, the apparatus further comprises a removable lid that, when closed, defines an upper surface of an oven chamber for placement of the semiconductor wafer. In another embodiment, a majority of heat generated by the heater during operation is dissipated through the upper surface of the removable lid, when closed. In another embodiment, the upper surface is from about 10 mm to about 20 mm above the rotatable hot plate. In another embodiment, the apparatus further comprises one or more pins that engage with, and fix a rotational position of, the hot plate upon opening or closing the removable lid.

In another embodiment, a method for heating a semiconductor wafer is described. The method comprises positioning the semiconductor wafer above a hot plate and rotating the hot plate while maintaining the hot plate and the semiconductor wafer at an elevated temperature. In another embodiment, the step of rotating the hot plate further comprises rotating the semiconductor wafer together with the hot plate. In another embodiment, both the semiconductor wafer and the hot plate are rotated at a rotation speed from about 1 to about 3 revolutions per minute. In another embodiment, the method further comprises, prior to positioning the semiconductor wafer above the hot plate, rotating and heating the hot plate while maintaining it at an elevated temperature. In another embodiment, the semiconductor wafer is maintained at the elevated temperature for a period sufficient to effect a post exposure bake of the semiconductor wafer. In another embodiment, the elevated temperature is from about 65° C. to about 150° C. and the period is from about 30 seconds to about 5 minutes. In another embodiment, at the end of the period, the semiconductor wafer has a substantially uniform temperature. In another embodiment, the method further comprises, after rotating the semiconductor wafer while maintaining the hot plate at an elevated temperature, removing the semiconductor wafer from the hot plate at the same rotational position at which said semiconductor wafer was positioned above the hot plate initially. In such an embodiment, a position-sensing system may be employed to detect the rotational position of the hot plate 1 and to adjust the rotational position to be the same as when the heating process began. For instance, an electronic sensing system may be used to detect and adjust the rotational position of the hot plate 1. Or, for instance, a mechanical system may be used such as a notch or hole 20 in the hot plate 1 and a spring-loaded pin 21 in the body of the heating apparatus 10 configured to fit through the notch or hole 20, thereby fixing the rotational position of the hot plate 1 while the pin 21 is engaged with the notch or hole. In such a case, the pin 21 may be configured, for example, to engage the notch or hole 20 only during the final rotation of the hot plate 1 during a given heating step, thereby fixing the hot plate 1 at the correct rotational position for unloading and loading of the semiconductor wafer 5.

In another embodiment, a method for making a semiconductor chip is described. The method comprises exposing photo resist, which is coated on a semiconductor wafer, to a selected pattern of radiation. The method further comprises heating the semiconductor wafer according to any of the methods described above to effect a post exposure bake of the semiconductor wafer.

In another embodiment, a semiconductor chip itself is described, made according to any of the methods described above.

These and other embodiments are apparent from the following Detailed Description of Illustrative Embodiments.

### BRIEF DESCRIPTION OF THE DRAWINGS

FIG. 1 is a representation of an illustrative semiconductor wafer having circular temperature variations.

FIG. 2 is a representation of an illustrative semiconductor wafer having non-circular temperature variations.

FIG. 3 is a representation of an illustrative semiconductor heating apparatus.

### DETAILED DESCRIPTION OF ILLUSTRATIVE EMBODIMENTS

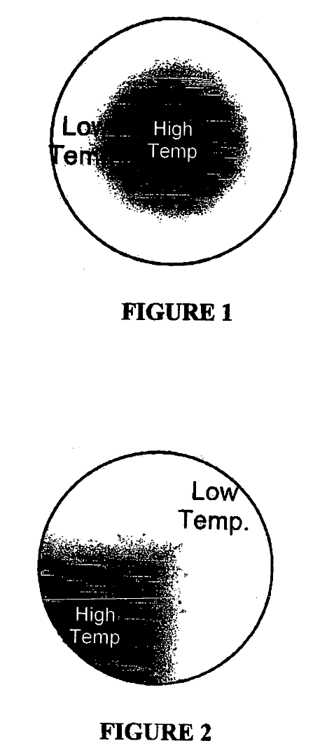

As used herein, “circular temperature variations” refer to temperature variations that are substantially uniform along any given radius of the wafer. For a wafer having only circular temperature variations, the temperature at any point of a given circle on the wafer that is concentric with the wafer will be substantially constant. FIG. 1 depicts a wafer having circular temperature variations, where higher levels of shading are used to represent higher wafer surface temperature.

In contrast, “non-circular temperature variations” are not uniform along any given radius of the wafer, such that the temperature at any point on a concentric circle on the wafer is not necessarily constant. FIG. 2 depicts a wafer having non-circular temperature variations.

As discussed above, the adjustment of hot plate heater settings (i.e., the oven power) can be used to overcome mainly the circular temperature variations encountered during semiconductor heating operations such as the PEB. To this end, the art has focused on the control of multiple zonal heater settings, based on a number of measured quantities. The tighter temperature uniformity tolerances needed for control of ever smaller critical dimensions, however, requires the strict regulation of both circular and non-circular temperature variations. Thus, rotation of the hot plate and/or the semiconductor wafer is employed to address this requirement.

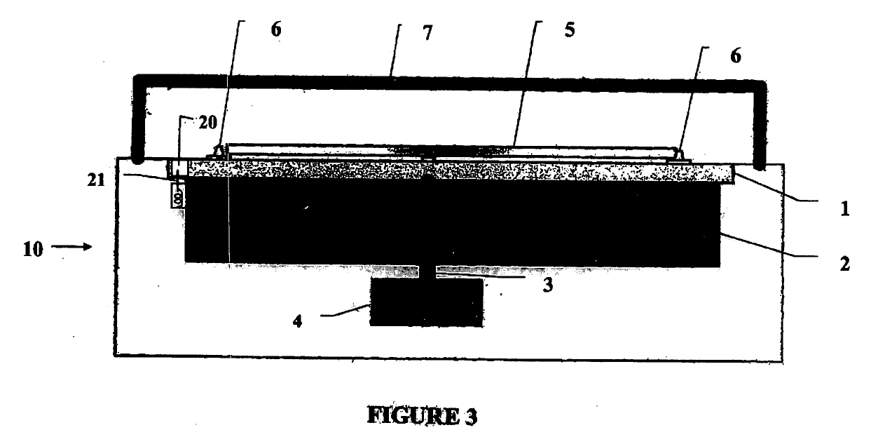

FIG. 3 depicts a representative, non-limiting heating apparatus 10 according to the present invention for heating a semiconductor wafer 5 is depicted in FIG. 3. The semiconductor wafer 5 is shown to better illustrate the functioning of the heating apparatus 10; it is not an element of the heating apparatus 10 itself. The semiconductor wafer 5 may be of any size or shape, such as a conventional 300 mm diameter circular wafer, although smaller or larger diameter wafers may be used. The heating apparatus 10 comprises a rotatable hot plate 1 which is disposed above a heater 2. The hot plate 1 may be circular, rectangular, or any other shape suitable for functioning as a platform for supporting the semiconductor wafer 5 and transferring heat from the heater 2 to the upper surface of the hot plate 1 and to or toward the semiconductor wafer 5 disposed on or above the upper surface. For instance, the hot plate 1 may be circular and about 300 mm in diameter or larger (e.g., from about 300 mm to about 500 mm in diameter). The heater 2 may be equipped with one or more individually controllable heating elements (not shown) to heat various positions or zones. For example, a number of circular heating elements may be placed within the heater 2 at varying radii about its center. The output of the heating elements may be governed, using one or more feedback control loops, by measurements from one or more temperature sensors (not shown) at various locations within the oven environment. Such locations can include the spaces (if present) between the surface of the rotatable hot plate 1, the spaces between the hot plate and a lid 7, and/or the semiconductor wafer 5 and/or between the surface of the heater 2 and the rotatable hot plate 1.

The heater 2 is shown as disposed directly on the surface of the rotatable hot plate 1, in which case it will often be desirable to employ a high-temperature lubricant, such as graphite, silicon, or a petroleum, mineral oil-, or synthetic oil-based material. Ball bearings or other conventional means may also be used to facilitate rotation of the rotatable hot plate 1 relative to the heater 2. In other embodiments, the rotatable hot plate 1 may be spaced apart from the heater (e.g., at a distance from about 10 μm to about 1 mm and typically from about 20 μm to about 200 μm) by being positioned on an axle 3 of an electrical motor or other rotation device 4 at the desired spacing.

As shown in FIG. 3, one or more holders 6 may be affixed to the surface of the rotatable hot plate 1 in order to position the semiconductor wafer 5 above the rotatable hot plate 1 during heating operations (e.g., during the PEB). The axle 3 of the rotation device 4 (or a small extension thereof on the surface of the rotatable hot plate 1) may also be used in conjunction with the holders 6 to facilitate alignment of the semiconductor wafer 5 at its center as well as at its outer edges. The semiconductor wafer 5 may be positioned directly on the surface of the rotatable hot plate 1 or, as shown in FIG. 3, it may be spaced apart from this surface (e.g., at a distance from about 10 μm to about 5 mm and typically from about 20 μm to about 500 μm).

In the embodiment shown in FIG. 3, the semiconductor wafer 5, by virtue of its positioning on the surface of the rotatable hot plate 1, will rotate at the same rate as the hot plate 1. In other embodiments, it may be desirable rotate the semiconductor wafer 5 but not the hot plate 1. This may be achieved, for example, by extending the axle 3 and/or other positioning elements (not shown), which are moved by the rotation device 4, through the hot plate so that the axle and/or positioning elements act on the semiconductor wafer 5, but not on the hot plate. In such embodiments, in fact, the hot plate 1 may be missing altogether. In other embodiments the semiconductor wafer 5 may remain in a fixed position above the rotatable hot plate 1. In still other embodiments, more than one rotation device may be employed to rotate the semiconductor wafer 5 and rotatable hot plate 1 at different rates, or even in opposite directions. In still further embodiments, the heater may rotate while the semiconductor wafer 5 and/or the hot plate 1 remain fixed.

The heating apparatus 10 will also generally include a lid 7 which can fully, or at least substantially fully, enclose an upper surface and possibly also the peripheral (or side) surfaces of an oven chamber in which the semiconductor wafer 5 is heated. The lid 7 may be solid and airtight or it may be vented to allow hot air to pass out of the heating apparatus 1. The lid 7 may be removable, by any conventional means, to facilitate the repeated removal/repositioning of the wafers in the heating apparatus 10, as may be required in the overall semiconductor manufacturing process. The lid 7 may be removable, for example, by means of a hinge (not shown) upon which the lid 7 can pivot between an open and a closed position. The lid 7 may also be completely separable. In general, a substantial portion (e.g., the majority) of heat generated during heating of the semiconductor wafer 5 is dissipated through the surface of the removable lid 7. The lid 7 typically provides good conduction of heat from the oven chamber to the external environment, such that a generally constant and unidirectional flow of heat is established, which helps maintain wafer temperature uniformity throughout the heating operation. Generally, the upper surface of the lid is proximate (e.g. from about 1 mm to about 50 mm above) the rotatable hot plate 1 and semiconductor wafer 5. Often, the removable lid 7 is from about 10 mm to about 20 mm above the rotatable hot plate 5. However, any dimensions may be implemented.

In one embodiment, the heating operation (e.g., the PEB) is characterized by the insertion of the semiconductor wafer 5 before heating, and removal of the semiconductor wafer 5 after heating, in the same rotational position. That is, the semiconductor wafer 7 will undergo substantially a whole number of complete rotations (e.g., 1, 2, 3, 4, or 5 complete rotations) during the PEB or other heating operation. This allows for all the exposure of all portions of the wafer to all regions (i.e., temperature environments) within the oven chamber for substantially the same time. For example, the wafer may be rotated during heating at a rotation speed of 1½ revolutions per minute (RPM) for a period of 80 seconds, such that two whole rotations are completed by the end of the heating period. In this manner, the heating period may, in one embodiment, determine the wafer rotational speed (or vice versa), in that a whole number of rotations are desired over the course of heating. In accordance with such modes of operation, the heating apparatus may be equipped with an interface for the input (e.g., manually or through a computer) of one or more variables including the rotation speed, bake time, total number of rotations, and bake temperature. A subset of these variables (e.g., bake time and total rotations) may also be input for the determination of other variables (e.g., rotation speed and bake temperature) thereby insuring that the heating operation is performed according to desired parameters.

The wafer may be rotated at a rotation speed from, e.g., about 0.5 to about 5 RPM or from about 1 to about 3 RPM. Although any rotation speed may be used, these particular rotation speeds are not so excessive as to introduce any substantial extraneous air currents in the depicted embodiment which might adversely impact wafer temperature uniformity during heating. Such rotation speeds apply to both the hot plate 1 and the semiconductor wafer 5, in the particular embodiment depicted in FIG. 3, and where both the hot plate 1 and semiconductor wafer 5 are rotated together. These rotation speeds also generally apply to the hot plate and/or wafer in other embodiments where only the hot plate 1 is rotated, where only the wafer 5 is rotated, where only the heater 2 is rotated, or where the hot plate 1 and the wafer 5 are rotated at different rotational speeds and/or in different directions.

In another particular embodiment, when the lid 7 is opened or closed (e.g., at the conclusion of one heating operation or beginning of the next heating operation, respectively), the rotational position of the wafer 5 and/or hot plate 1 is fixed by the use of one or more pins or other alignment elements (not shown). The use of pins, for example, which engage with the hot plate 1 to fix a rotational position of the hot plate 1 and the wafer 5 (when both are rotated together, as depicted in FIG. 3), can further ensure that the wafer 5 and the hot plate 1 have undergone a fixed whole number of rotations during the heating operation. In a similar manner, in other embodiments, the rotational position of the hot plate 1 alone or the wafer 5 alone may be fixed upon opening or closing the removable lid 7.

In operation, the semiconductor wafer 5 may be positioned above the hot plate 1 (e.g., directly on, or spaced apart from, the surface of the hot plate 1), and the hot plate 1 may be rotated while maintaining the hot plate 1 and the semiconductor wafer 5 at an elevated temperature. As discussed above, both the semiconductor wafer 5 and hot plate 1 may be rotated together by positioning the wafer 5 above the hot plate 1 using, for example, the holders 6. In one embodiment, the hot plate 1 is rotated at an elevated temperature (e.g. with the lid 7 closed), even prior to the introduction of the wafer 5 into the heating apparatus 10 (e.g., after opening the lid 7). This “pre-rotation” can reduce temperature gradients on the hot plate 1 before the heating operation is begun and may be conducted with the hot plate 1 alone or in conjunction with the semiconductor wafer 5 used in the immediately preceding heating operation. The use of automated manufacturing techniques such as robotics allows for the transfer of semiconductor wafers into and out of the heating apparatus 10 within a matter of several seconds, and often in two seconds or less.

The elevated temperature is maintained in the oven chamber of the heating apparatus 10 for a period sufficient to effect the desired heating operation. In the case of PEB, the semiconductor wafer 5 may be maintained at an elevated temperature ranging from about 65° C. (150° F.) to about 150° C. (300° F.), and more particularly from about 95° C. (205° F.) to about 125° C. (255° F.), for a period from about 30 seconds to about 5 minutes and typically from about 60 seconds to about 90 seconds. However, any time period and elevated temperature may be used. Thus, semiconductor wafer heating (e.g., in PEB operations) may be provided such that a substantially uniform temperature of the wafer 5 is established both during temperature ramping and at the end of the procedure. As described above, in the case of PEB, temperature uniformity is especially critical during the first 10-20 seconds of the bake, when most of the chemical reactions that ultimately govern the precision of the features of the semiconductor wafer 5 occur. Substantial uniformity between the temperatures of any two given points of the surface of the semiconductor wafer 5 means that the temperatures of the two points vary by no more than about 0.5° C. (0.9° F.). However, although temperature uniformity across the entire semiconductor wafer 5 surface may vary by no more than about 0.5° C. (0.9° F.), the temperature may be even more uniform, such as a variance across the entire semiconductor wafer 5 surface of no more than about 0.25° C. (0.45° F.), or even no more than about 0.20° C. (0.36° F.).

The heating apparatuses and methods described herein may be employed in an overall semiconductor manufacturing process including the conventional photolithography steps of vapor priming the wafer 5, spin coating the wafer 5 with resist, soft baking the resist-coated wafer 5 prior to exposure, alignment/exposure, post exposure baking, development, hard baking after development, and development/inspection. Particular semiconductor heating operations that may be used include, for example, soft baking, post exposure baking, and/or hard baking. As described herein, is the apparatuses and methods described herein may be particularly suitable for use in post exposure baking, where temperature uniformity is recognized as being critically important for semiconductor quality. Thus, the apparatuses and methods described herein may be included in an overall semiconductor manufacturing processes including exposing photo resist, which is coated on the semiconductor wafer 5, to a selected pattern of radiation and heating the semiconductor wafer 5 according to methods described herein to effect a post exposure bake. Semiconductor chips manufactured in this manner have good critical dimension control and other important advantages.

Throughout this disclosure, various aspects are presented in a range format. The description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual whole and fractional numbers within that range, for example, 1, 2, 2.6, 3, 4, 5, and 6. This applies regardless of the breadth of the range.

In view of the above, it will be seen that several advantages may be achieved and other advantageous results may be obtained. As various changes could be made in the above apparatuses and methods without departing from the scope of the present disclosure, it is intended that all matter contained in this application, including all theoretical mechanisms and/or modes of interaction described above, shall be interpreted as illustrative only and not limiting in any way the scope of the appended claims.

What is claimed is:

1. An apparatus for heating a semiconductor wafer, the apparatus comprising:
a heater; and
a rotatable hot plate disposed above the heater and configured to transfer heat from the heater to an upper surface of the hot plate.

2. The apparatus of claim 1, wherein said rotatable hot plate is spaced apart from said heater.

3. The apparatus of claim 1, further comprising one or more holders on said rotatable hot plate for positioning said semiconductor wafer above said rotatable hot plate.

4. The apparatus of claim 3, wherein said one or more holders space said rotatable hot plate apart from said semiconductor wafer.

5. The apparatus of claim 4, further comprising a temperature sensor for measuring a temperature between said rotatable hot plate and said semiconductor wafer.

6. The apparatus of claim 1, further comprising a removable lid that, when closed, defines an upper surface of an oven chamber for placement of said semiconductor wafer.

7. The apparatus of claim 6, wherein a majority of heat generated by said heater during operation is dissipated through said upper surface, when said removable lid is closed.

8. The apparatus of claim 6, wherein said upper surface is from about 10 mm to about 20 mm above said rotatable hot plate.

9. The apparatus of claim 6, further comprising one or more pins that engage with, and fix a rotational position of, said hot plate upon opening or closing said removable lid.

10. The apparatus of claim 1, wherein said heater comprises a plurality of individually controllable heating elements.

11. A method for heating a semiconductor wafer, the method comprising
(a) positioning said semiconductor wafer above a hot plate,
(b) rotating said hot plate while maintaining said hot plate and said semiconductor wafer at an elevated temperature.

12. The method of claim 11, wherein step (b) further comprises rotating said semiconductor wafer together with said hot plate.

13. The method of claim 12, wherein both said semiconductor wafer and said hot plate are rotated at a rotation speed from about 1 to about 3 revolutions per minute.

14. The method of claim 11, further comprising, prior to step (a), rotating and heating said hot plate while maintaining it at an elevated temperature.

15. The method of claim 11, wherein said semiconductor wafer is maintained at said elevated temperature for a period sufficient to effect a post exposure bake of said semiconductor wafer.

16. The method of claim 15, wherein said elevated temperature is from about 65° C. to about 150° C. and said period is from about 30 seconds to about 5 minutes.

17. The method of claim 15, wherein, at the end of said period, said semiconductor wafer has a substantially uniform temperature.

18. The method of claim 15, wherein said period determines, or is determined by, a rotation speed of said semiconductor wafer.

19. The method of claim 11 further comprising, after step (b), removing said semiconductor wafer from said hot plate at the same rotational position at which said semiconductor wafer was positioned above said hot plate in step (a).

20. A method for making a semiconductor chip, the method comprising
(a) exposing photo resist, which is coated on a semiconductor wafer, to a selected pattern of radiation;
(b) positioning said semiconductor wafer above a hot plate; and
(c) rotating said hot plate while maintaining said hot plate and said semiconductor wafer at an elevated temperature.
